(19) United States
(12) Patent Application Publication
(10) Pub. No.: US 2005/0126497 A1
(43) Pub. Date: Jun. 16, 2005

(54) Platform assembly and method

(76) Inventors: Jerry D. Kidd, Granbury, TX (US); Danny R. Caudle, Granbury, TX (US)

Correspondence Address: HUNTON & WILLIAMS LLP, 1601 BRYAN STREET, ENERGY PLAZA - 30TH FLOOR, DALLAS, TX, 75201, US

(21) Appl. No.: 10/955,899

(22) Filed: Sep. 30, 2004

Related U.S. Application Data
(60) Provisional application No. 60/507,559, filed on Sep. 30, 2003.

(51) Int. Cl. C23C 16/00; B05D 3/12

(52) U.S. Cl. 118/730; 427/240

(57) ABSTRACT

An exemplary platform assembly and method is provided to facilitate a uniform deposition of a depositant on substrates. The platform assembly can include a platform, satellite tables, and an actuator. The platform moves upon a support structure, while the satellite tables, supporting the substrates, rotate on the platform. The actuator moves the platform and satellite tables, presenting the substrate to the depositant dispenser. A resistance to movement of the platform forces a rotation of the satellite tables. Additionally, a method is provided that includes positioning a platform on a support structure and positioning the substrates on the satellite tables. The platform is then moved within a dispersion area of the depositant dispenser. A stationary gear, coupled to the support structure, resists motion of the platform, thereby forcing each of the plurality of satellite tables to rotate.

### CROSS-REFERENCE TO RELATED APPLICATIONS

Pursuant to 35 U.S.C. § 119(e), this Application claims the benefit of and hereby incorporates by reference for all purposes United States Provisional Patent Application Ser. No. 60/507,559 entitled Platform Assembly and Method, naming Jerry D. Kidd and Danny R. Caudle as inventors, filed Sep. 30, 2003.

### TECHNICAL FIELD OF THE INVENTION

This invention relates in general to the field of deposition technology for plating and coating materials and more particularly to a platform assembly and method to facilitate uniform coating.

### BACKGROUND OF THE INVENTION

Various deposition technologies exist for plating and coating materials. These various technologies include, but are not limited to, vacuum deposition or physical vapor deposition (“PVD”), chemical vapor deposition (“CVD”), sputtering, and ion plating. In such deposition technologies, one concern is the ability to uniformly coat an object among the object's different sides. Current practices involve the arrangement of depositant or element dispensers about the object to allow coating of the several sides. Once coating has occurred, the several sides of the object are measured for uniformity to ensure that the desired coating thickness has been obtained. If the coating is uneven, the process of recoating must be undertaken. However, in such a recoating process, the desired thickness can inadvertently be exceeded.

### SUMMARY OF THE INVENTION

From the foregoing it may be appreciated that a need has arisen for a platform assembly and method for facilitating a uniform deposit of a depositant on a substrate. In accordance with the present invention, a system and a method for facilitating a uniform deposit of a depositant on a substrate are provided that substantially eliminate one or more of the disadvantages and problems outlined above.

According to one aspect of the invention, a platform assembly, arranged and designed to facilitate a uniform deposit of a depositant on a substrate via presentment of the substrate to a depositant dispenser, has been provided. The platform assembly comprises a platform, a plurality of satellite tables, and an actuator. The platform is rotatably coupled to a support structure. The support structure is operable to rotate the platform around a central axis. The plurality of satellite tables are rotatably coupled to the platform and at least one of the plurality of satellite tables is operable to support the substrate. The actuator actuates the rotation of the platform and actuates the rotation of each of the plurality of satellite tables in the same direction. The rotation of the platform presents the substrate to the depositant dispenser and the rotation of the at least one of the plurality of satellite tables presents the substrate to the depositant dispenser.

According to another aspect of the invention, a platform assembly, arranged and designed to facilitate a uniform deposit of a depositant on a substrate via presentment of the substrate to a depositant dispenser, has been provided. The platform assembly comprises a platform, an actuator, a plurality of satellite tables, and a plurality of gears. The platform is movably coupled to a support structure. The support structure allows movement of the platform. The actuator forces movement of the platform. At least one of the plurality of satellite tables is operable to support the substrate and the plurality of satellite tables are rotatably coupled to the platform. The plurality of gears are adjoined to the stationary gear. The stationary gear is coupled to the support structure and resists movement of the platform. The resistance to movement forces the actuation of the plurality of gears, which forces actuation of each of a plurality of satellite tables.

According to yet another aspect of the invention, a method of facilitating a uniform deposit of a substrate via presentment of the substrate to a depositant dispenser has been provided. The method comprises movably positioning a platform on a support structure; positioning the substrate on one of a plurality of satellite tables, wherein each of the plurality of satellite tables are coupled to a satellite table gear; moving the platform within a proximity of a dispersion area of the depositant dispenser; and forcing each of the plurality of satellite tables to rotate via a stationary gear that resists movement of the platform, wherein the resistance to motion by the stationary gear forces rotation of a main gear, and the rotation of the main gear, interacting with each of the satellite table gears, forces rotation of the satellite tables.

According to yet another aspect of the invention, a method of facilitating a uniform deposit of a substrate via presentment of the substrate to a depositant dispenser has been provided. The method comprises movably positioning a platform on a support structure; positioning the substrate on a satellite table, the satellite table being rotably coupled to the platform; applying an electrical signal to the substrate; moving the platform and substrate within a proximity of a dispersion area of the depositant dispenser; and rotating the satellite table when the substrate is within the dispersion area of the depositant dispenser.

The present invention provides a profusion of technical advantages that may include the capability to controllably, repeatably, and reliably facilitate a uniform deposit of a substrate via presentment of the substrate to a depositant dispenser.

Another technical advantage of the present invention may include the capability to reduce the time and effort needed to obtain a uniform coating on a substrate or object.

Another technical advantage of the present invention may include the capability to efficiently use depositants to minimize the consumption of depositants, which in turn can reduce costs—especially when the depositants utilized are expensive precious metals such as gold and platinum.

Other technical advantages may be readily apparent to one skilled in the art after review of the following figures, description, and claims.

### BRIEF DESCRIPTION OF THE DRAWINGS

For a more complete understanding of the present invention and the advantages thereof, reference is now made to the following brief description, taken in connection with the accompanying drawings and detailed description, wherein like reference numerals represent like parts, in which:

FIG. 1 is a perspective view of a configuration of a platform assembly with a table top and a plurality of satellite tables, according to an aspect of the present invention;

FIG. 2 is a side view illustrating configurations of component parts of a platform assembly;

FIG. 3 is a side top perspective view of a main shaft bearing housing and a main shaft;

FIG. 4 is a side view of a main shaft bearing housing with a ring and a stationary gear;

FIG. 5 is a side perspective view illustrating an interaction between a drive transfer gear and a stationary gear;.

FIG. 6 is a top perspective view showing a metal support plate, a main gear, and a drive gear;

FIG. 7 is a close-up view showing a metal support plate and a drive gear;

FIG. 8 is a top perspective view of a table top;

FIG. 9 is a top perspective view, illustrating an interaction between a main gear and a satellite table gear;

FIG. 10 is a close up view of FIG. 9;

FIG. 11 is a sectional view, illustrating a configuration of a satellite table within a table;

FIG. 12 is a top perspective view of an isolated bearing;

FIG. 13 is a side perspective view of a satellite table with a satellite table gear and an inner sleeve;

FIG. 14 is a side perspective view, illustrating a removability of a satellite table;

FIG. 15 is a top perspective view of a satellite table, having a larger satellite table mounted thereto; and

FIG. 16 is a side perspective view, illustrating a particular use of a platform assembly.

### DETAILED DESCRIPTION OF THE INVENTION

It should be understood at the outset that although an exemplary implementation of the present invention is illustrated below, the present invention may be implemented using any number of techniques, whether currently known or in existence. The present invention should in no way be limited to the exemplary implementations, drawings, and techniques illustrated below, including the exemplary design and implementation illustrated and described herein. Additionally, the drawings contained herein are not necessarily drawn to scale.

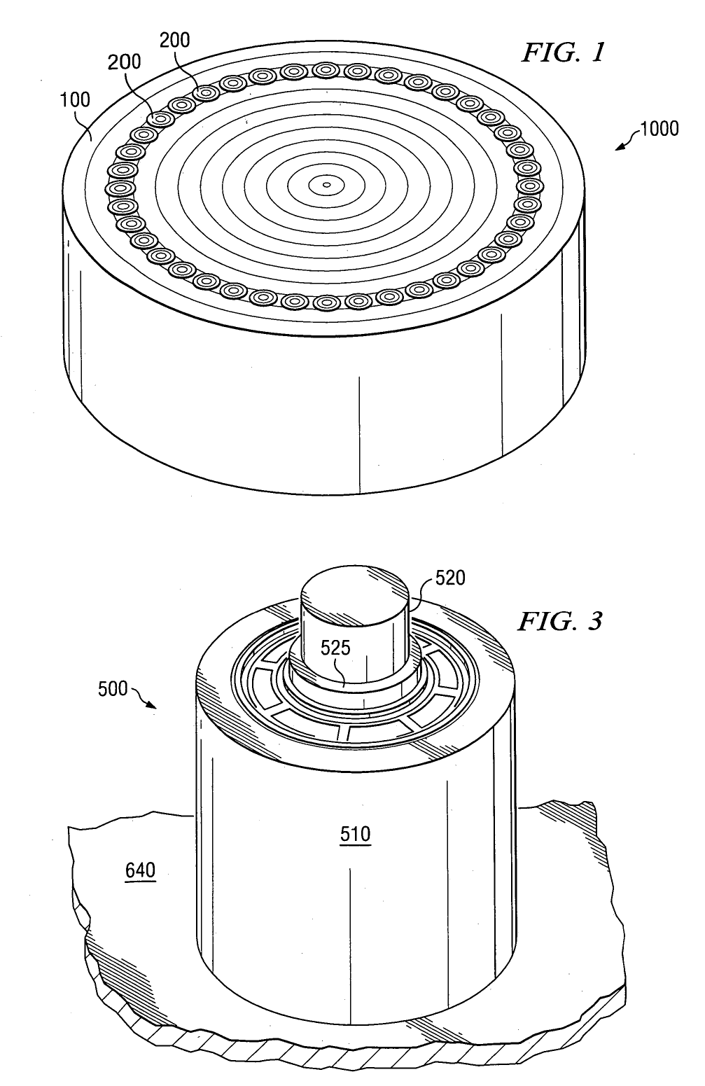

FIG. 1 generally shows a perspective view of a configuration of a platform assembly 1000. While a specific configuration of a platform assembly will be described with reference to FIG. 1 and other figures, it should be expressly understood that other configurations can be utilized. The platform assembly 1000 in the configuration of FIG. 1 includes a platform or table 100 having satellite tables 200 imbedded therein. In this configuration, the table 100 generally rotates the satellite tables 200 about a central axis, while each of the satellite tables 200 rotate about their own respective axis. Such an operation can be viewed as a rotation (the satellite tables 200) within a rotation (the table 100). In an element or depositant coating operation, an object or substrate (not shown) can be placed on any one or all of the satellite tables 200. Generally, the movement of the table 100 (e.g., by the rotation or other means) presents the object to an element dispenser (not shown) while the rotation of the satellite tables 200 presents multiple sides of the object to the element dispenser. With such a presentment of multiple sides of an object, a more uniform coating of the object can be obtained.

While the table 100 and satellite tables 200 are described in FIG. 1 with regards to a specific configuration, it should be understood that other configurations can be utilized—including not only those that are now known, but also those that will be later developed. For example, the table 100 and/or satellite tables 200 can have a square, oval, or triangular design. Additionally, the surface configuration of the table 100 can take on various configurations including, but not limited to, a flat surface, a horizontal surface, a vertical surface, an inclined surface, a curved surface, a curvilinear surface, a spherical surface or a helical surface. Other design configurations and modifications should become apparent to one of ordinary skill in the art after review of this specification.

While the table 100 has been described as moving in a rotational path, it should be understood that in some configurations the table 100 can be stationary—e.g., allowing the satellite tables 200 to rotate while the element dispensers are presented to the satellite tables 200. Additionally, in a configuration where the table 100 moves, other forms of motion can be utilized including, but not limited to, a tilted rotation, movement on a guided track, or the like. To a certain degree, the ultimate configurations will be dependent upon the object being coated and the element, which is being dispensed thereon. Accordingly, the configurations described herein are intended as only exemplifying some of the many configurations, which can be utilized.

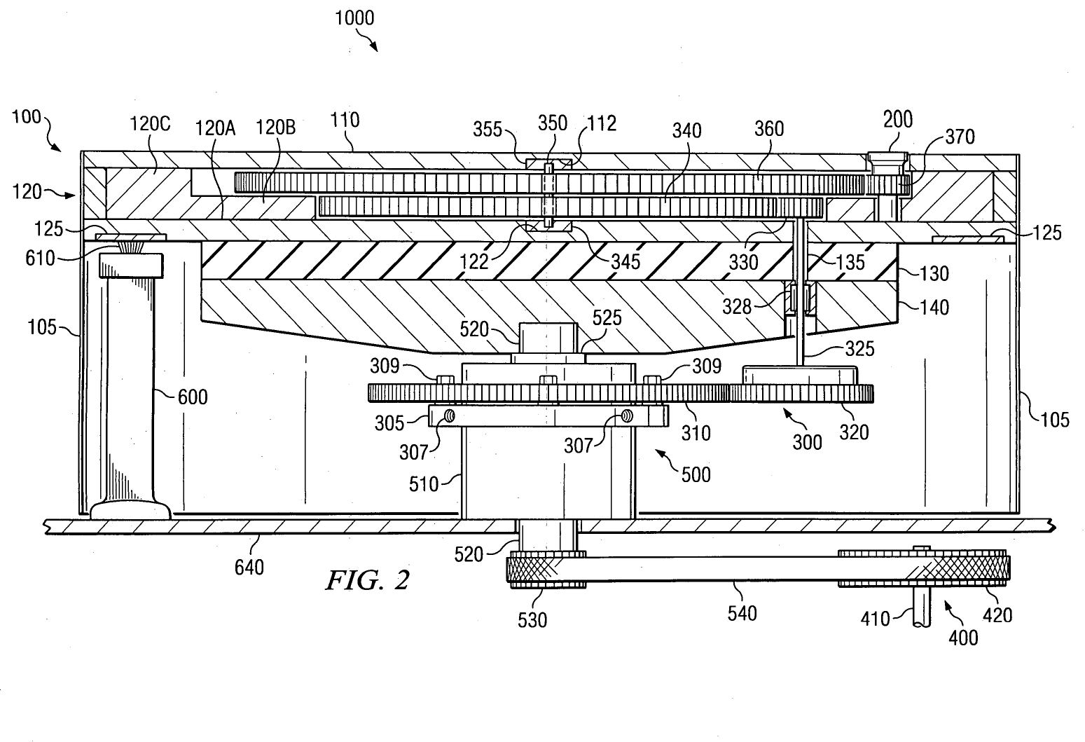

FIG. 2 is a side cut-away view of a configuration of platform assembly 1000. The table 100 is shown in phantom view to expose various component parts that can be utilized in configurations of the platform assembly 1000. With the description of the configuration of the component parts of the platform assembly 1000, it should be understood that such configurations are only exemplary of several designs that can be utilized. Other configurations will become apparent to one of ordinary skill in the art after review of the specification herein.

While the configuration described with reference to FIG. 2 is particularly suitable for an ion coating process, the platform assembly 1000 can be used with other coating techniques. In the configuration of FIG. 2, the platform assembly 1000 includes a table 100, a plurality of satellite tables 200, a gearing system 300, an actuator 400, and a support system 500. The interaction of these component parts in this configuration is generally as follows: the support system 500 supports and allows movement of the table 100; the actuator 400 actuates movement of the table 100; and the gearing system 300, reacting to movement of the table 100, transfers a portion of the force of the actuator 400 into movement of the plurality of satellite tables 200. Other configurations can have alternative interactions, depending on the component parts and configurations associated with those component parts. For ease of illustration, only one satellite table 200 is shown in the configuration of FIG. 2. In practice, more than one satellite table 200 can be used.

In the configuration of FIG. 2, the support system 500 includes a main shaft bearing housing 510, a main shaft 520, and a sprocket 530. A plurality of ball bearings (not shown) are disposed between the main shaft 520 and the main shaft bearing housing 510. The ball bearings, as should become apparent to one of ordinary skill in the art, allow support of an axial load (e.g., the weight of the table 100) while facilitating rotation of a structure (e.g., rotation of the table 100). At an upper end of the main shaft 520 is a shelf 525, upon which the table 100 rests—namely an undertable 140 of the table 100.

A lower annular base of the main shaft bearing housing 510 rests upon a base plate 640 while the main shaft 520 protrudes through an opening machined in the base plate 640. Coupled to a lower end of the main shaft 520, underneath the base plate 640 is the sprocket 530. Rotation of the sprocket 530 rotates the main shaft 520, which in turn rotates the table 100. Other configurations of a system, which support and facilitate movement of the table 100 should become apparent to one of ordinary skill in the art, including for example, but not limited to, structures that support and facilitate movement of the table 100 at an angle.

Working in conjunction with the sprocket 530 to rotate the table 100 is the actuator 400. The actuator 400 in this configuration includes a motor driven shaft 410, coupled to an actuator gear 420. A mechanical linkage 540 such as a belt, chain, or the like connects the mechanical movement of the actuator gear 420 to the sprocket 530. A motor (not shown) rotates the motor driven shaft 410 and the actuator gear 420, which through the mechanical linkage 540 causes the sprocket 530 to rotate. Other types of actuators and associated configurations, which provide mechanical actuation, should become apparent to one of ordinary skill in the art. For example, movement of the table 100 can be designed to move upon a sliding track—the actuator 400 being designed to have a thrust force to move the support system 500 and hence the table 100. Virtually any type of movement, which facilitates the presentment of the object on the table 100 to the element dispenser, can be utilized. With such types of movements, the appropriate associated actuator 400 can be used.

The general component parts of the table 100 in this configuration are an undertable 140, an insulator piece 130, a metal support plate 120, a table top 110, and a shield 105. As indicated above, the undertable 140 can be mounted on top of the shelf 525 of the main shaft 520. The shape of the undertable 140 is designed to disperse the point load support by the shelf 525 to a support of the broader cross-sectional area of the table 100.

Mounted to the top of the undertable 140 is an insulator piece 130, which as will be described below, can facilitate a particular ion coating process. The inclusion of the insulator piece 130 in this configuration illustrates the flexibility of the platform assembly 1000 in relation to a particular coating technique being utilized.

Coupled to the top of the insulator piece 130 is a metal support plate 120. An annular ring 125 can be pressed onto the bottom of the metal support plate 120 to facilitate an ion coating process. The annular ring 125 is preferably made of a conductive material, facilitating such a process—e.g., copper. For illustrative purposes only, an RF/DC adapter 600 has been shown—a component part that can be used in an ion coating process. The RF/DC adapter 600 includes a beryllium brush 610 which contacts the annular ring 125 and bridges the gap between the RF/DC adapter 600 and the annular ring 125 of the metal support plate 120 establishing electrical communication between the RF/DC adapter 600 and the metal support plate 120. The passage of electrical energy through the RF/DC adapter 600, beryllium brush 610, and annular ring 125 disperses through the metal support plate 120. The insulator piece 130, preferably made of a nonconductive material such as mycarta, helps to electrically isolate the electrical charge in the metal support plate 120 from the undertable 140. More details of an ion coating process, which can be utilized with the configuration of FIG. 2 will be described below.

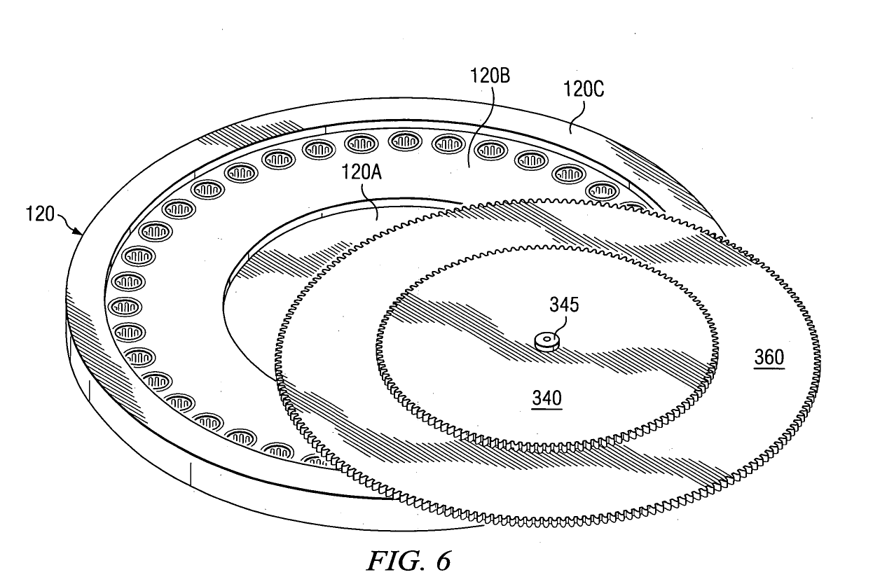

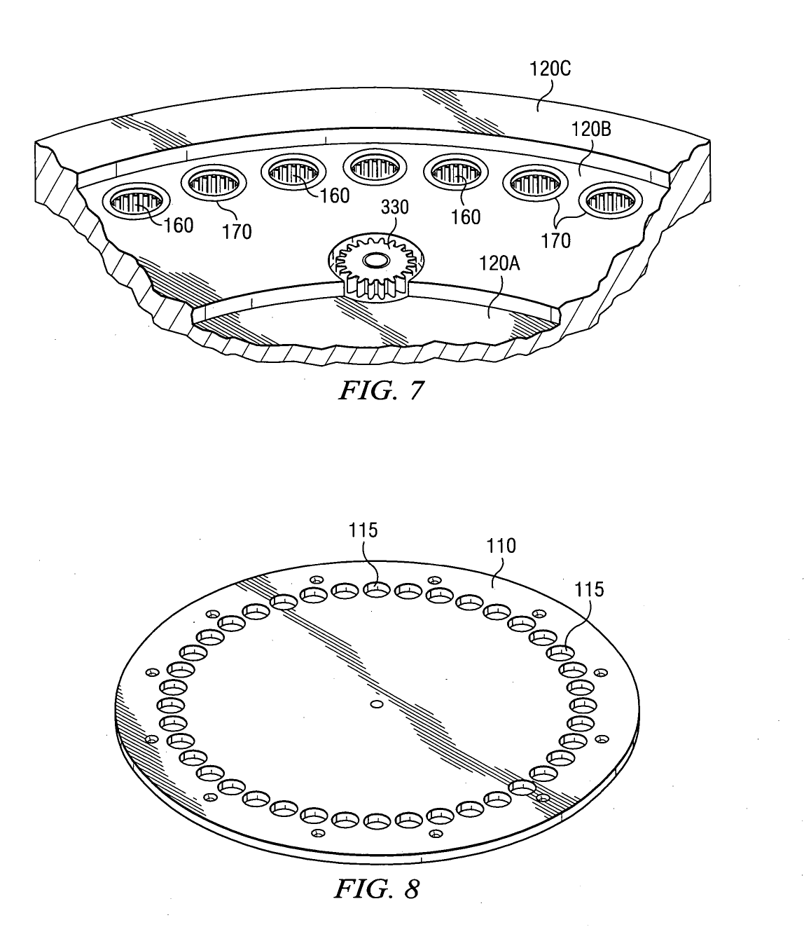

The metal support plate 120 takes on an annular stair-step appearance (seen better in FIGS. 6 and 7), forming three levels: a lower level 120A, an intermediate level 120B, and a top level 120C. Each of the levels (the lower level 120A, the intermediate level 120B, and the top-level 120C) help support component parts of the gearing system 300. More details of the lower level 120A, the intermediate level 120B, and the top level 120C will be described below with reference to FIGS. 6, 7, 9, and 10. Mounted to the top of the metal support plate 120 is the table top 110, described in more detail with reference to FIG. 8.

Mounted to the sides of the metal support plate 120 is the shield 105. The shield 105 in this configuration extends down from the metal support plate 120 almost to the base plate 640 and circumscribes the internal component parts—e.g., the insulator piece 130, the undertable 140, the drive transfer gear 320, the stationary gear 310, and the main shaft bearing housing 510. The shield 105 protects these component parts from exposure to the element, being dispersed upon the objects.

The gearing system 300 in this configuration works to translate a portion of the force in which the actuator 400 imparts upon the table 100 into a rotation of each of the plurality of satellite tables 200. The gears within the gearing system 300 can include a stationary gear 310, a drive transfer gear 320, a direct drive coupling gear 330, a drive gear 340, a main gear 360, and a satellite gear 370. The stationary gear 310 in this configuration is a non moveable-gear that resists rotation. While the stationary gear 310 can be placed in a variety of locations, the stationary gear 310 of FIG. 2 is positioned on an outside periphery of the main shaft bearing housing 510. Other locations can include, but are not limited to, a mounting upon a set of columns instead of mounting to the main shaft bearing housing 510. Aiding the coupling of the stationary gear 310 to the main shaft bearing housing 510, in this configuration is a ring 305. The ring 305 is placed around the outside periphery of the main shaft bearing housing 510 and secured in place via a tightening of set screws or studs (not shown), moved radially inwardly through threaded holes 307 in the ring 305 up against the main shaft bearing housing 510. The stationary gear 310 is then coupled to the ring 305 via one or more coupling pieces 309 such as bolts, studs, or the like. Preferably, the coupling pieces 309 are wrapped in nylon bushings to electrically isolate the stationary gear 310 from the ring 305 and the main shaft bearing housing 510.

The coupling of the ring 305 to the main shaft bearing housing 510 allows adjustment of the location of the ring 305/stationary gear 310. For example, the ring 305 can be released from main shaft bearing housing 510 and repositioned at a different vertical location along the main shaft bearing housing 510.

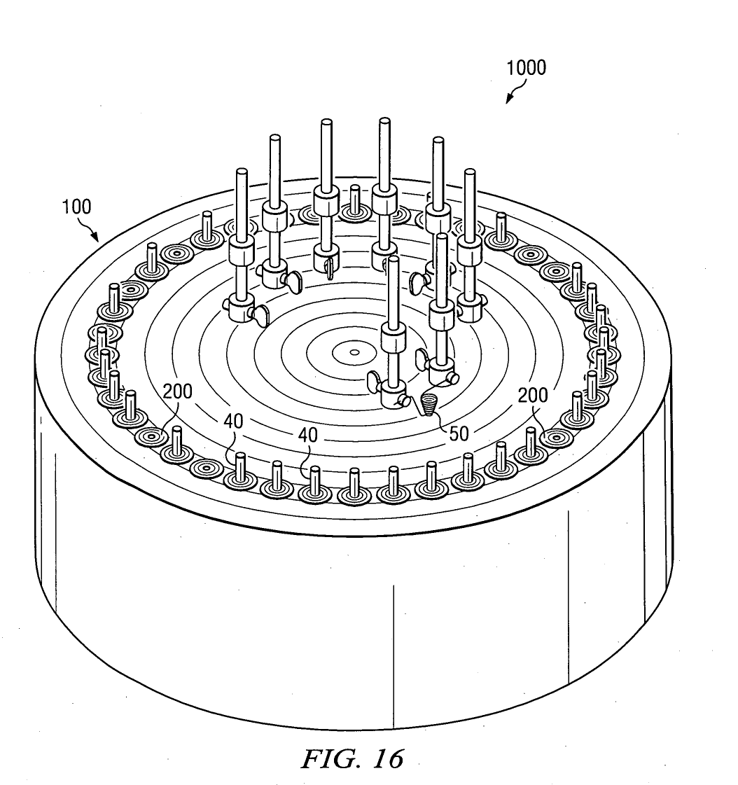

The stationary gear 310 has teeth that interact with teeth of the drive transfer gear 320. The spider gear or drive transfer gear 320 is ganged to the direct drive coupling gear 330 via a drive shaft.325. The drive shaft 325 passes through a needle bearing 328 in the undertable 140 and a hole 135 in the insulator piece 130 to facilitate this ganging. The needle bearing 328 can be mounted in nylon, other plastics, or the like to electrically insulate the needle bearing 328 from the undertable 140. The use of such non-conductive materials will be described below with reference to FIG. 16.

Upon rotation of the sprocket 530, main shaft 520 and table 100, a rotational force is transferred through the undertable 140 to the needle bearing 328 forcing the drive shaft 325 and the drive transfer gear 320 to rotate with the table 100. The spider gear or drive transfer gear 320 (having teeth geared with the stationary gear 310) begins to rotate, walking around the stationary gear 310—the stationary gear 310 resisting rotation. Facilitating rotation of the drive transfer gear 320 is the needle bearing 328.

A portion of the force transferred from the actuator 400 to the table 100 can be viewed as being transferred to the drive transfer gear 320 in the interaction of the drive transfer gear 320 with the stationary gear 310—that is, the rotational force provided by the actuator 400 is roughly equivalent to the force to rotate the table 100, in isolation, plus the force to rotate the gearing system 300, in isolation.

As the drive transfer gear 320 rotates and walks about the stationary gear 310 (better seen in FIG. 5), the drive shaft 325 and the direct drive coupling gear 330 rotate. In turn, the direct drive coupling gear 330, having teeth geared with teeth of the drive gear 340, forces rotation of the drive gear 340 and main gear 360 (the main gear 360 being ganged to the drive gear 340). Finally, rotation of the main gear 360, having teeth geared with teeth of the satellite table gears 370, forces a rotation of the plurality of satellite table gears 370, which are coupled to the plurality of satellite tables 200—allowing the satellite tables 200 to rotate. As referenced above, the drive gear 340 and main gear 360 are ganged—that is, they move with one another. To facilitate such ganging, any type of coupling technique known to those skilled in the art can be utilized—including coupling techniques that are now known and those that will be later developed. Facilitating movement of the drive gear 340 and the main gear 360 is a lower bearing 345 and an upper bearing 355. Both the lower bearing 345 and the upper bearing 355 can be ball bearings. Other suitable bearings will become apparent to one of ordinary skill in the art. The lower bearing 345 is housed within a cutout 122 of the metal support plate 120 while the upper bearing 355 is housed within a cutout 112 of the table top 110. Between the upper bearing 355 and the lower bearing 345 is a rod 350.

While such a gearing system 300 is described in this configuration, it is to be expressly understood that other configurations may be utilized to rotate the plurality of satellite tables 200. For example, in a simpler configuration, the satellite table gears 370 can interact directly with a stationary gear 310 that is mounted for the particular movement of the table 100. Such a configuration can include, with reference to FIG. 2, an internally threaded stationary gear circumscribing an outer periphery of the satellite table gears 370. In this configuration, the satellite table gears 370 (moved by the table 100) can rotate with an interaction with the internally threaded stationary gear 310. Other similar configurations will become apparent to one of ordinary skill in the art.

FIG. 3 shows a top perspective view of a configuration of a support system 500, namely the main shaft bearing housing 510 and the main shaft 520. As indicated above, a plurality of ball bearings (not seen from this view) can be disposed between the main shaft 520 and the main shaft bearing housing 510, allowing the main shaft 520 to rotate. The shelf 525 and the base plate 640 are also shown.

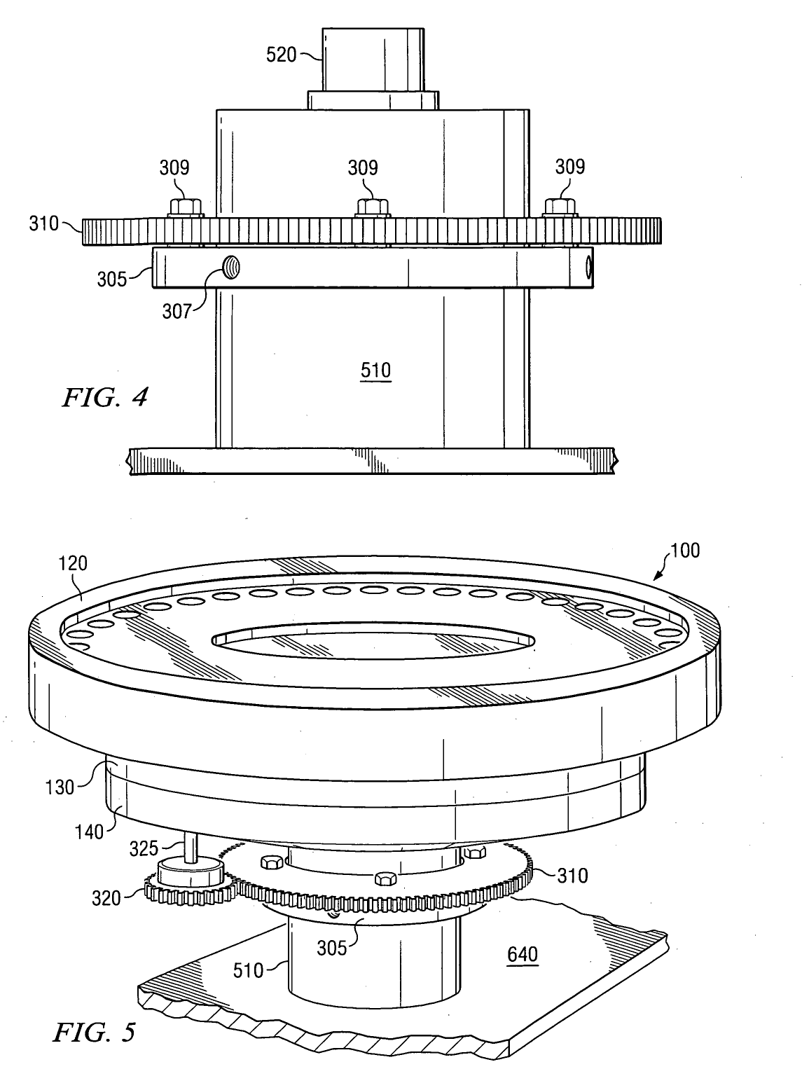

FIG. 4 shows a side view of a configuration of a main shaft bearing housing 510, having a ring 305 and a stationary gear 310 coupled thereto. As indicated above, the ring 305 can be placed around the outside periphery of the main shaft bearing housing 510 and secured in place via a tightening of set screws or studs (not shown), moved radially inwardly through threaded holes 307 in the ring 305 up against the main shaft bearing housing 510. The stationary gear 310 is coupled to the ring 305 via one or more coupling pieces 309 such as bolts, studs, or the like. Preferably, the coupling pieces 309 are wrapped in nylon bushings to electrically isolate the stationary gear 310 from the ring 305 and main shaft bearing housing 510. In this configuration, the stationary gear 310 and the main shaft bearing housing 510 do not come into contact with one another. The use of the main shaft bearing housing 510 as a support for the stationary gear 310 has certain structural advantages. As an example, intended for illustrative purposes only, a cylindrical shaped structure has the ability to resist torque loads, which may be imparted upon the stationary gear 310 during operation. While such a configuration has been described, it is to be understood that other configurations can be used to support the stationary gear 310. For example, the main shaft bearing housing 510 and the associated couplings (e.g., ring 305) can take on a variety of different shapes. Additionally, the stationary gear 310 can be supported by columns or the like. Other configurations will become apparent to one of ordinary skill in the art.

FIG. 5 is a side perspective view illustrating a configuration similar to FIG. 2. For ease of illustration, the shield 105 has been removed. In this configuration, three layers of the table 100 are shown: the undertable 140, the insulator piece 130, and the metal support plate 120. The main shaft bearing housing 510 is mounted atop a base plate 640, the ring 305 is secured in place on the main shaft bearing housing 510, and the stationary gear 310 is coupled to the ring 305. Extending down from the undertable 140 is the drive shaft 325 and the drive transfer gear 320. The teeth of the drive transfer gear 320 interact with the teeth of the stationary gear 310. When the table 100 begins to rotate, the drive transfer gear 320 walks about the stationary gear 310, thereby forcing the drive shaft 325 to rotate.

FIGS. 6-10 show a top perspective view of configurations of several component parts referenced in FIG. 2. As referenced above, the metal support plate 120 can be perceived as an annular stair stepped structure having three step levels: the lower level 120A, the intermediate level 120B, and the top level 120C. The lower level 120A houses and allows the coupling of the drive gear 340 to the metal support plate 120. A lower bearing 345, such as a ball bearing, is coupled to the drive gear 340 and can be positioned within a cutout 122 within the metal support plate 120 (seen in FIG. 2). Additionally, the direct drive coupling gear 330 (seen in FIG. 7 on the lower level 120A, but disposed within the intermediate level 120B) interacts with the drive gear 340 on the lower level 120A. The intermediate level 120B houses the main gear 360 and the plurality of satellite table gears 370. Disposed within the intermediate level 120B underneath the satellite table gears 370 are the satellite bearings 160 and bearing housings 170. The top level 120C supports the table top 110.

FIG. 6 shows the main gear 360 coupled to the drive gear 340 and flipped upside down to expose the lower bearing 345. The main gear 360 and drive gear 340 are resting upon the metal support plate 120, with the three step levels—the lower level 120A, the intermediate level 120B, and the top level 120C—exposed.

FIG. 7 shows a close-up view of the direct drive coupling gear 330. The direct drive coupling gear 330 is housed within a cutout of the intermediate level 120B. A plurality of satellite bearings 160 housed within the bearing housings 170 can also be seen.

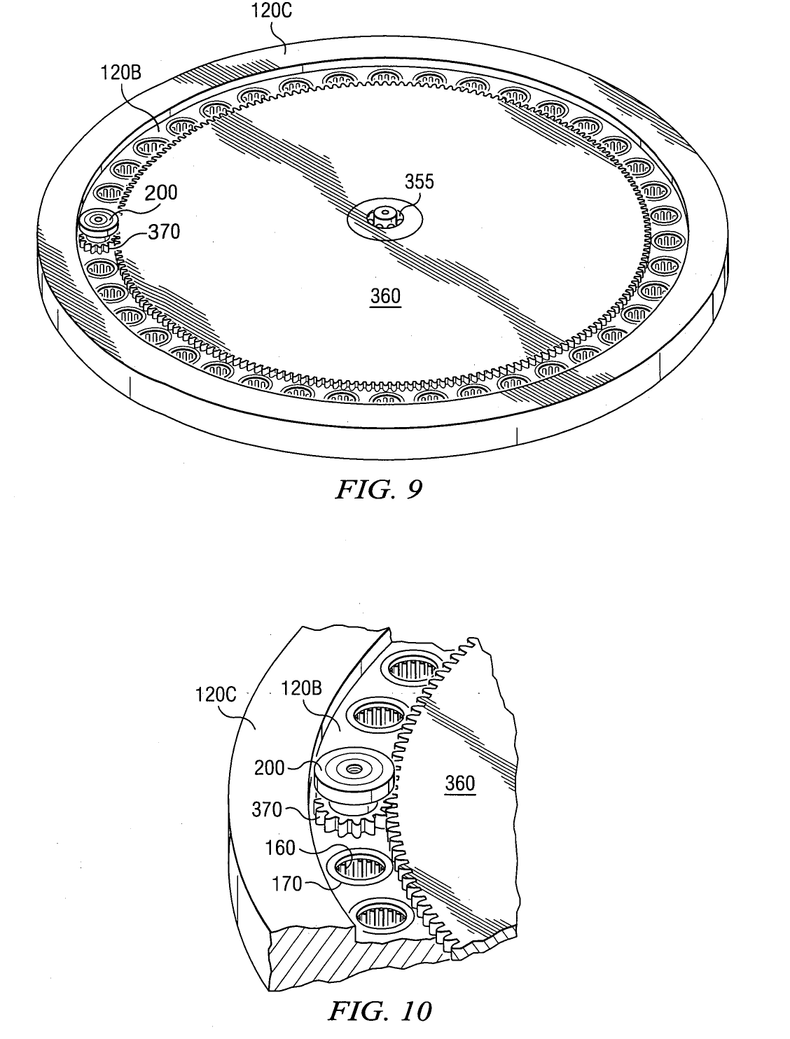

FIG. 8 shows a top perspective view of the table top 110. The table top 110 is mounted on top of the top level 120C (seen in FIG. 2) and includes a plurality of holes 115 designed to house the satellite tables 200. The table top 110 protects internal gears, namely the main gear 360 and the satellite table gears 370 (those, which would be exposed as seen in FIG. 9).

FIG. 9 shows the interaction between the main gear 360 and a single satellite table gear 370, having a satellite table 200 coupled thereto. While only one satellite table gear 370 and satellite table 200 is shown in FIG. 9, more satellite table gears 370 and satellite tables 200 can be used in practice. As the main gear 360 rotates, so will the satellite table gear 370 and the satellite table 200. The upper bearing 355 can also be seen.

FIG. 10 shows in more detailed view the interaction between the main gear 360 and the satellite table gear 370, having a satellite table 200 coupled thereto. Additionally, the plurality of satellite bearings 160, housed with bearing housings 170, can also be seen.

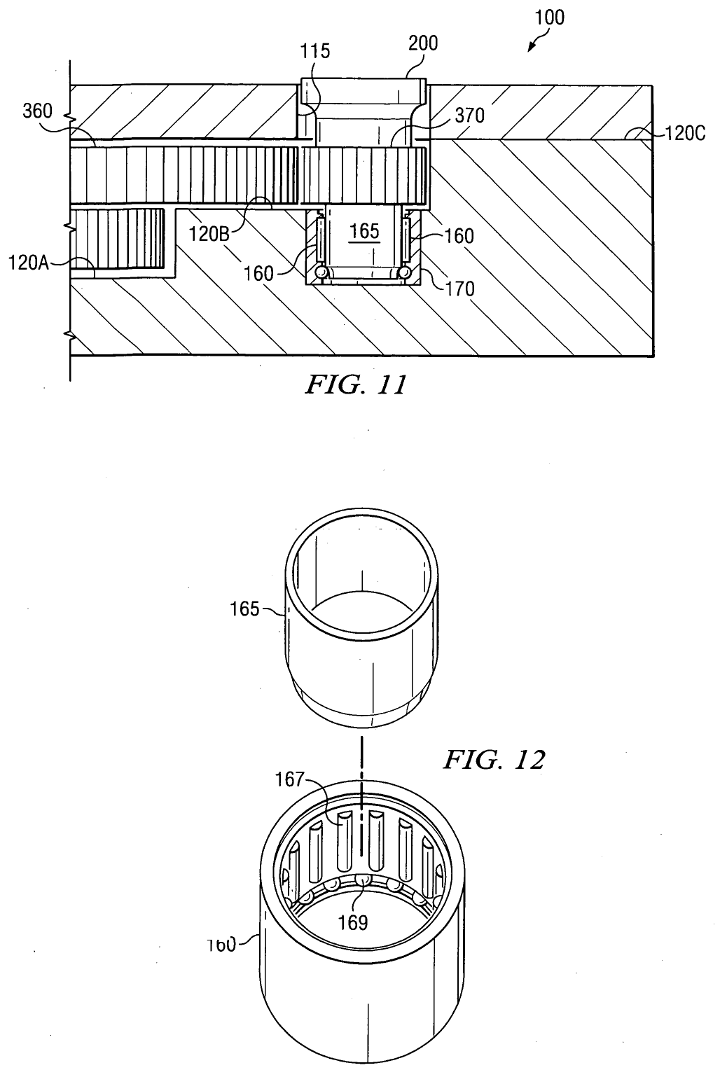

FIG. 11 shows a sectional view, illustrating a configuration of the satellite table 200 within the table 100. Coupled to the satellite table 200 is the satellite table gear 370 and a satellite inner sleeve 165, which can be removably positioned within the satellite bearings 160. As discussed above with reference to FIG. 2, the main gear 360 forces rotation of the satellite table gear 370. In turn, the satellite table gear 370 forces rotation of the satellite table 200. Facilitating this rotation is the satellite inner sleeve 165/satellite bearings 160. To help stabilize the rotation of the satellite tables 200, the satellite bearings 160 preferably include a bearing that can support an axial/thrust load and a bearing that can support a radial load. One bearing that can accomplish both is a combination bearing. A combination bearing suitable for such a purpose is a Combined Needle/Thrust Ball bearing model no NKIA-5901, manufactured by Consolidated Bearing Company of Cedar Knolls, N.J. The satellite bearings 160 are positioned within a bearing housing 170, cut out of the intermediate level 120B of the metal support plate 120.

The satellite table 200, the satellite table gear 370, and the satellite inner sleeve 165 can be viewed as one piece, removably positioned within the respective housings of each level, namely the hole 115 in the table top 110 (the satellite table 200), the area between the main gear 360 and the wall of the metal support plate 120 (the satellite table gear 370), and the satellite bearings 160 (the satellite inner sleeve 165).

FIG. 12 shows an isolated view of a configuration of the satellite bearing 160. A satellite inner sleeve 165 can be disposed within the satellite bearing 160. The satellite bearing 160 can provide a radial load support via needle bearings 167 and a thrust load support via thrust ball bearings 169. While such a bearing has been shown and described, it should be expressly understood that other configurations and component parts can be utilized—including not only those that are now known, but also those that will be later developed.

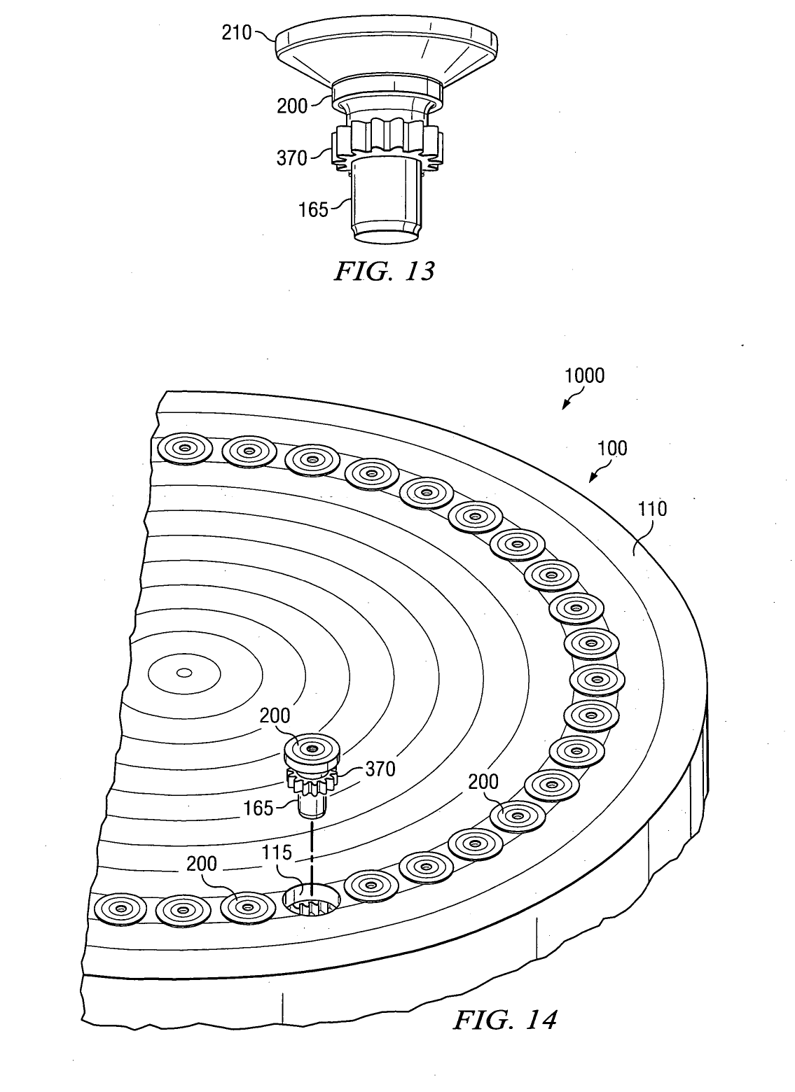

FIG. 13 is a side perspective view of a configuration of the satellite table 200. A satellite table gear 370 and a satellite inner sleeve 165 have been coupled to the satellite table 200. While such a configuration is shown in this configuration, it is to be expressly understood that other configurations may use other component parts to facilitate support of the satellite tables 200. Also shown in this configuration is a larger diameter satellite table 210 coupled to the top of the satellite table 200. Details of such a larger diameter satellite table 210 will be discussed in further details below.

FIG. 14 shows a configuration of the platform assembly 1000 of FIG. 1 and illustrates a removeability of the satellite table 200, the satellite table gear 370, and the satellite inner sleeve 165 as one piece. The satellite table 200, the satellite table gear 370, and the satellite inner sleeve 165 have been removed through the hole 115 in the table top 110. When the satellite table 200, the satellite table gear 370, and the satellite inner sleeve 165 are placed into their respective housings, the satellite table 200 preferably lies flush with the table top 110 as shown in FIG. 14. While the satellite tables 200 are flush with the table top 110 in this configuration, in other configurations the satellite tables 200 may be inset or lie just outside the table top 110. The ability to remove these components as one piece facilitates repairs that may become necessary.

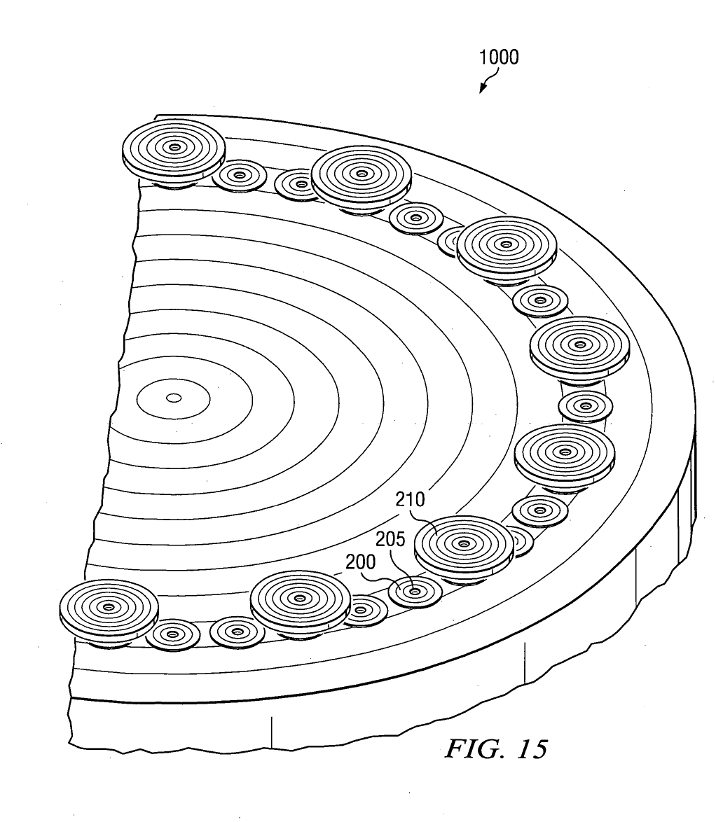

FIG. 15 illustrates another configuration of a platform assembly 1000. In this configuration, the satellite tables 200 include holes 205, which allow the attachment of larger diameter satellite tables 210. The larger diameter satellite tables 210 can support larger objects for presentment to the element dispenser. The coupling of such larger diameter satellite tables 210 to the satellite tables 200 can be a variety of techniques commonly known in the art including, but not limited to, threaded bolt-and-screw connections and the like.

FIG. 16 illustrates an exemplary use of a configuration of the platform assembly 1000, namely a use with plasma plating. While this exemplary use will be described with reference to plasma plating, it should be expressly understood that the platform assembly 1000 can be utilized in a variety of other different plating and/or coating processes/techniques—including not only in such processes/techniques that are now known, but also in processes/techniques that will be later developed. For illustration of this use, reference will be made to platform assembly 1000, described in FIGS. 1 and 2. The platform assembly 1000 in FIG. 16 generally includes a plurality of substrates or objects 40 mounted on the satellite tables 200. Centrally located above the rotating table 100 is a plurality of depositant or element dispensers 50 which, in this configuration, are tungsten wire baskets. The element dispensers 50 are part of an element dispensing system, which can include various pieces of equipment used to support the plasma plating of the object 40—e.g., a vacuum chamber (not shown), which facilitates operational conditions needed in plasma plating. Once such operating conditions are achieved, an element—e.g., in this illustrative configuration, any metal, such as a metal alloy, gold, titanium, chromium, nickel, silver, tin, indium, lead, copper, palladium, silver/palladium or a variety of others—can be placed within the element dispenser 50 and evaporated or vaporized to form a plasma. Generally, the plasma will contain positively charged ions from the element and will be attracted to the negatively charged object 40 where it will form a deposition layer on the object 40.

To facilitate the negative charging of the object 40, the platform assembly 1000 can be arranged and designed to provide an electrically conductive path between an electrical energy source and the object 40. For example, in some configurations, the table 100 can be constructed of a metal or electrically conductive material such that the negative electrical charge can pass therethrough. In such configurations, insulators can be positioned to provide electrical isolation from areas of the table 100 in which electrical conductivity is not desired. In other configurations, the table 100 can include electrically conductive material at certain locations within the table 100 to provide a direct path to the satellite tables 200.

With reference to FIG. 2, the table 100 can be generally constructed of electrically conductive materials, having insulators at appropriate locations. The introduction of energy, such as a dc signal and a radio frequency signal (rf/dc signal), to the table 100 occurs through the RF/DC adapter 600. While not shown, the RF/DC adapter 600 can be coupled to a DC/RF mixer, which takes a dc signal (e.g., generated by a dc power supply at a negative voltage) and an rf signal (e.g., generated by a transmitter), and mixes them for introduction of an rf/dc signal to the RF/DC adapter 600.

In the coupling of the RF/DC adapter to the DC/RF mixer, care is taken as to not energize undesirable component items—e.g., the base plate 640 upon which the RF/DC adapter 600 rests. As the table 100 can be rotating in operation, the RF/DC adapter 600 includes the beryllium brush 610, described above with reference to FIG. 2. The beryllium brush 610 scrapes an annular ring 125, which is mounted to the metal support plate 120. The scraping of the beryllium brush 610 with the annular ring 125 transfers the rf/dc signal from the the RF/DC adapter 600 to the metal support plate 120. The annular ring 125 is preferably made of an electrically conductive material such that the introduction of the rf/dc signal will easily spread to the entire annular ring 125. Additionally, the placement of the annular ring 125 is preferably coordinated with the placement of the satellite table(s) 200 such that a conductive path is easily established between the annular ring 125 and the satellite table(s) 200. As can be seen in FIG. 2, the annular ring 125 is located directly underneath the satellite table(s) 200. To further enhance the transfer of the rf/dc signal to the satellite table(s) 200, a conductive material can be utilized between the annular ring 125 and satellite table(s) 200.

Upon introducing the rf/dc signal to the annular ring 125, the rf/dc signal can be transmitted through component parts, which are made of conductive materials—e.g, the metal support plate 120, the main gear 360, and the drive gear 340. Insulators can be utilized to electrically isolate other component parts. For example, the insulator piece 130, preferably made of a non-conductive material such as mycarta, helps to isolate the metal support plate 120 from the undertable 140. Additionally, the needle bearing 328 can be mounted in nylon, other plastics, or the like to electrically insulate the needle bearing 328 from the undertable 140.

The rf/dc signal, while having difficulty, could potentially be transmitted to the drive transfer gear 320 and stationary gear 310. Therefore, the coupling between the stationary gear 310 and the ring 305 preferably includes nylon bushings to electrically isolate the stationary gear 310 from the ring 305 and the main shaft bearing housing 510. While examples of isolation and conductivity have been provided, it is to be expressly understood that the configurations of the invention are not limited to these examples. Other configurations within the scope of the invention should become apparent to one of ordinary skill in the art.

In seeking a uniform coating of objects, many factors can come into play, including, but not limited to, the dispersion range of the element, the distance between the element dispenser 50 and the object 40, the shape of the object 40, the element being dispensed, the thickness of a layer of the element desired on the object 40, the closeness of the other element dispensers 50, and the amount of time needed for the element to deposit on the object 40. If the object 40 has a cylindrical configuration such as that shown in FIG. 16, a uniform distribution can occur by rotating the object 40 through one complete rotation in front of a dispersion range of the element dispenser 50. As the concentration can vary across this dispersion range, preferably the object 40 will be rotated at least two times in front of the dispersion range of the element dispenser 50 in a single presentment of the object to the element dispenser 50. Several exposures to the element dispenser 50 and/or element dispensers 50 can help achieve the desired coating thickness. Because the configuration described in FIG. 2 has a rotation of the table 100, which is related by gears to the rotation of the satellite table 200, a ratio can be established. With this ratio being established, the satellite tables 200 will rotate a certain number of times in relation to one rotation of the table 100. In the illustrative configuration of FIG. 2, the ratio of rotation of the satellite tables 200 to the table 100 is preferably 6 to 1. While such ratios are given, it is to be understood that other configurations may have different ratios between the gears, and some configurations may not have ratios at all.

With the configuration shown in FIG. 16, it can be seen that several different elements can be placed in various element dispensers 50. With such a configuration, a first layer of one element can be coated on the object 40; and then, a second layer of another element can be coated on the object 40; and, so forth. The benefit of such a configuration is greatly expounded in applications where specific operating conditions must be met before the coating process can begin—that is, configurations where a lot of time and effort are involved with setting up the coating process. Additionally, because the objects 40 are rotating on the satellite tables 200, the element dispensers 50 in the configuration of FIG. 16 need to only be set up on one side of the objects 40. However, in other configurations, the element dispensers 50 can be set up on both sides of the objects 40.

Any of a variety of element dispenser 50 types, shapes, and configurations may be used in the present invention. For example, the element dispenser 50 may be provided as a tungsten basket, a boat, a coil, a crucible, a ray gun, an electron beam gun, a heat gun, or any other structure.

In the illustrative configuration of FIG. 16, the element dispensers 50 are generally heated through the application of an electric current to the element dispenser 50. However, any method or means of heating the element within the element dispenser 50 may be used for this configuration.

With the use of the various equipment used in plasma plating, a gas, such as argon, may be introduced into the vacuum chamber at a desired rate to raise the pressure in the vacuum chamber to a desired pressure or to within a range of pressures.

Once all of the operating parameters and conditions are established (e.g., objects 40 coupled to satellite tables 200, element dispensers 50 positioned in place, elements placed in element dispensers 50, system placed in vacuum chamber, vacuum created, argon gas injected), plasma plating can occur. The table 100 can begin to rotate, forcing rotation of all the satellite tables 200 and corresponding objects 40. The rf/dc signal can be passed through to the table 100 and objects 40. Then, the element dispensers 50 can be heated through the application of an electric current to the element dispenser 50 to evaporate or melt the element—thereby forming plasma. The plasma will preferably include positively charged element ions, which will be attracted to the negative potential in the objects 40. As the objects 40 rotate in front of the element dispensers 50, uniform coating occurs. Multiple shots of different elements can occur on the same object 40 by simply exposing the object 40 to different elements on different complete rotations. With this general basic description, it is to be understood that several other operating steps and/or parameters can be utilized.

Thus, it is apparent that there has been provided, in accordance with the present invention, a system and method for coating an object that satisfies one or more of the advantages set forth above. Although the preferred configuration has been described in detail, it should be understood that various changes, substitutions, and alterations can be made herein without departing from the scope of the present invention, even if all, one, or some of the advantages identified above are not present. For example, in configurations using ion coating techniques, the dc signal and the radio frequency signal may be electrically coupled to the substrate using virtually any available electrically conductive path. The present invention may also be implemented using any of a variety of materials and configurations. For example, any of a variety of vacuum pump systems, equipment, and technology could be used in the present invention. The present invention also does not require the presence of a gas, such as argon, to form a plasma. Additionally, movement of the table 100 can occur in a variety of different manners including sliding on tracks and oscillating rotations. These are only a few of the examples of other arrangements or configurations of the system and method that are contemplated and covered by the present invention.

The various components, equipment, substances, elements, and processes described and illustrated in the preferred configuration as discrete or separate may be combined or integrated with other elements and processes without departing from the scope of the present invention. The present invention may be used to coat virtually any material, object, or substrate using any of a variety of depositants. Other examples of changes, substitutions, and alterations are readily ascertainable by one skilled in the art and could be made without departing from the spirit and scope of the present invention.

1. A platform assembly, arranged and designed to facilitate a uniform deposit of a depositant on a substrate via presentment of the substrate to a depositant dispenser, the platform assembly comprising:
a platform rotatably coupled to a support structure, the support structure operable to rotate the platform around a central axis;
a plurality of satellite tables, wherein
the plurality of satellite tables are rotatably coupled to the platform, and
at least one of the plurality of satellite tables is operable to support the substrate; and
an actuator, which actuates the rotation of the platform and actuates the rotation of each of the plurality of satellite tables in the same direction, wherein
the rotation of the platform presents the substrate to the depositant dispenser, and
the rotation of the at least one of the plurality of satellite tables presents the substrate to the depositant dispenser.

2. The platform assembly of claim 1, wherein the at least one of the plurality of satellite tables rotates the substrate at least 720° during a single presentment of the substrate to the depositant dispenser.

3. The platform assembly of claim 1, wherein
the rotation of the plurality of satellite tables are effected by a force of a force transfer system, and
the force of the force transfer system is effected by movement of the platform.

4. The platform assembly of claim 3, wherein the platform includes
an undertable;
an insulator piece, coupled to the undertable;
a support plate coupled to the undertable;
a table top coupled to the support plate; and
a shield coupled to the support plate.

5. The platform assembly of claim 4, wherein the force transfer system includes:
a drive transfer gear, which interacts with teeth of a stationary gear;
a direct drive coupling gear, ganged to the drive transfer gear;
a drive gear, which interacts with the teeth of the direct drive coupling gear;
a main gear, ganged to the drive gear; and
a plurality of satellite table gears, which interact with teeth of the main gear.

6. The platform assembly of claim 3, wherein a ratio of a complete rotation of each of the plurality of satellite tables to a complete rotation of the platform is at least 4 to 1.

7. The platform assembly of claim 3, wherein a ratio of a complete rotation of each of the plurality of satellite tables to a complete rotation of the platform is at least 6 to 1.

8. The platform assembly of claim 3, wherein the force transfer system utilizes at least one gear.

9. The platform assembly of claim 8, wherein the at least one gear includes at least one set of ganged gears.

10. The platform assembly of claim 9, wherein the at least one gear includes at least two sets of ganged gears.

11. The platform assembly of claim 8, wherein
the at least one gear includes a stationary gear,
the stationary gear resists movement of the platform, and
the resistance of movement of the platform by the stationary gear effects movement of the plurality of satellite tables.

12. The platform assembly of claim 11, wherein the central axis of the platform passes through a center point of the stationary gear.

13. The platform assembly of claim 11, wherein
the at least one gear further includes a drive transfer gear, and
the drive transfer gear has an axis eccentrically located from the central axis of the platform.

14. The platform assembly of claim 3, wherein the rotatable coupling of at least one of the plurality of satellite tables is a removable coupling.

15. The platform assembly of claim 3, wherein
at least one of the plurality of satellite tables includes a mounting hole disposed therein, and
the mounting hole allows a mounting of a larger satellite table to the at least one of the plurality of satellite tables.

16. The platform assembly of claim 3, wherein the substrate is a bolt.

17. The platform assembly of claim 3, wherein the substrate is a stud.

18. The platform assembly of claim 3, wherein the depositant is a metal.

19. The platform assembly of claim 1, wherein the platform is configured to transfer an electrical signal to the plurality of satellite tables.

20. The platform assembly of claim 19, further comprising:
at least one insulator disposed between an upper portion of the platform and a lower portion of the platform, wherein
the electrical signal applied to the substrate charges the upper portion of the platform, and
the at least one insulator facilitates an electrical isolation of the upper portion of the platform.

21. The platform assembly of claim 20, wherein
the force transfer system transverses the entire platform through the upper portion of the platform and the lower portion of the platform, and
at least a portion of the force transfer system is non-conductive to allow electrical isolation in the upper portion of the platform.

22. The platform assembly of claim 1, wherein the rotatable coupling of at least one of the plurality of satellite tables to the platform includes a bearing designed to support a thrust load and a bearing designed to support an axial load.

23. The platform assembly of claim 22, wherein the bearing designed to support a thrust load and the bearing designed to support an axial load is a single bearing.

24. The platform assembly of claim 23, wherein the single bearing is a combination bearing.

25. A platform assembly, arranged and designed to facilitate a uniform deposit of a depositant on a substrate via presentment of the substrate to a depositant dispenser, the platform assembly comprising:
a platform moveably coupled to a support structure, the support structure allowing movement of the platform,
an actuator, which forces movement of the platform;
a plurality of satellite tables, wherein
at least one of the plurality of satellite tables is operable to support the substrate, and
the plurality of satellite tables are rotatably coupled to the platform; and
a plurality of gears, adjoined to a stationary gear, wherein
the stationary gear is coupled to the support structure,
the stationary gear resists movement of the platform,
the resistance to movement forces the actuation of the plurality of gears, and
the plurality of gears forces actuation of each of a plurality of satellite tables.

26. The platform assembly of claim 25, wherein the movement of the platform is a rotation around a central axis.

27. The platform assembly of claim 26, wherein the central axis of the platform passes through a center point of the stationary gear.

28. The platform assembly of claim 25, wherein the plurality of gears have at least one set of ganged gears.

29. The platform assembly of claim 25, wherein the plurality of gears include:
a drive transfer gear, which interacts with teeth of the stationary gear;
a direct drive coupling gear, ganged to the drive transfer gear;
a drive gear, which interacts with the teeth of the direct drive coupling gear;
a main gear, ganged to the drive gear; and
a plurality of satellite table gears, which interact with teeth of the main gear, wherein
the plurality of satellite table gears are coupled to the plurality of satellite tables,
movement of the platform transfers a force through the drive transfer gear, the direct drive coupling gear, the drive gear, the main gear, and the satellite table gears, and
the force transferred to the satellite table gears effects movement of the plurality of satellite tables.

30. The platform assembly of claim 25, wherein
the movement of the platform presents the substrate to the depositant dispenser, and
the at least one of the plurality of satellite tables rotates the substrates at least 720° during a single presentment of the substrate to the depositant dispenser.

31. The platform assembly of claim 25, wherein the rotatable coupling of at least one of the plurality of satellite tables is a removable coupling.

32. The platform assembly of claim 25, wherein
at least one of the plurality of satellite tables includes a mounting hole disposed therein, and
the mounting hole allows a mounting of a larger satellite table to the at least one of the plurality of satellite tables.

33. The platform assembly of claim 25, wherein the platform is configured to transfer an electrical signal to the plurality of satellite tables.

34. The platform assembly of claim 33, further comprising:
at least one insulator disposed between an upper portion of the platform and a lower portion of the platform, wherein
the electrical signal applied to the substrate charges the upper portion of the platform, and
the at least one insulator facilitates an electrical isolation of the upper portion of the platform.

35. The platform assembly of claim 34, wherein
the force transfer system transverses the entire platform through the upper portion of the platform and the lower portion of the platform, and
at least a portion of the force transfer system is non-conductive to allow electrical isolation in the upper portion of the platform.

36. A method of facilitating a uniform deposit of a substrate via presentment of the substrate to a depositant dispenser, the method comprising:
movably positioning a platform on a support structure;
positioning the substrate on one of a plurality of satellite tables, wherein each of the plurality of satellite tables are coupled to a satellite table gear;
moving the platform within a proximity of a dispersion area of the depositant dispenser; and
forcing each of the plurality of satellite tables to rotate via a stationary gear that resists movement of the platform, wherein
the resistance to motion by the stationary gear forces rotation of a main gear, and
the rotation of the main gear, interacting with each of the satellite table gears, forces rotation of the satellite tables.

37. The method of claim 36, further comprising:
supporting the plurality of satellite tables with a bearing designed to support a radial load and a bearing designed to support a thrust load.

38. The method of claim 36, further comprising:
rotating at least one of the plurality of satellite tables at least 720° during a single presentment of the substrate to the depositant dispenser.

39. The method of claim 36, wherein the movement of the platform is a rotational movement of the platform about a central axis.

40. The method of claim 39, further comprising:
applying at least two different types of depositants on the substrate, each of the at least two different types of depositants being applied on separate complete rotations of the platform.

41. The method of claim 36, further comprising:
applying an electrical signal to the substrate, and
insulating an upper portion of the platform from a lower portion of the platform, wherein the electrical signal applied to the substrate charges the upper portion of the platform.

42. The method of claim 41, wherein the platform is placed within a vacuum chamber, further comprising:
heating the depositant to a temperature at or above the melting point of the depositant to generate a plasma in the vacuum chamber.

43. The method of claim 42, wherein
applying the electrical signal to the substrate includes applying a dc voltage at a negative polarity, and
the plasma includes positive depositant ions.

44. A method of facilitating a uniform deposit of a depositant on a substrate via presentment of the substrate to a depositant dispenser, the method comprising:
movably positioning a platform on a support structure;
positioning the substrate on a satellite table, the satellite table being rotably coupled to the platform;
applying an electrical signal to the substrate;
moving the platform and substrate within a proximity of a dispersion area of the depositant dispenser; and
rotating the satellite table when the substrate is within the dispersion area of the depositant dispenser.

45. The method of claim 44, further comprising:
applying an rf signal to the substrate.

46. The method of claim 44, further comprising:
insulating an upper portion of the platform from a lower portion of the platform, wherein the electrical signal applied to the substrate charges the upper portion of the platform.

47. The method of claim 44, further comprising:
transferring a portion of a force applied to move the platform into a force utilized in rotating the satellite table.

48. The method of claim 44, further comprising:
resisting movement of the platform with a stationary gear, whereby said resistance to movement effects said transferring a portion of a force applied to move the platform.

49. The method of claim 44, wherein the movement of the platform is a rotational movement of the platform.

50. The method of claim 44, wherein the platform is placed within a vacuum chamber, further comprising:
heating the depositant to a temperature at or above the melting point of the depositant to generate a plasma in the vacuum chamber.

51. The method of claim 50, further comprising:
applying a dc voltage at a negative polarity to the substrate, wherein the plasma includes positive depositant ions.

52. The method of claim 51, further comprising:
applying at least two different types of depositants on the substrate, each of the at least two different types of depositants being applied on separate complete rotations of the platform.
